(19) United States
(12) Patent Application Publication
(10) Pub. No.: US 2009/0311839 A1
(43) Pub. Date: Dec. 17, 2009

(54) Method for manufacturing silicon carbide semicondutor device having trench gate structure

(75) Inventors: Shinichirou Miyahara, Nisshin-city (JP); Eiichi Okuno, Mizuho-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/457,600

(22) Filed: Jun. 16, 2009

(30) Foreign Application Priority Data
Jun. 17, 2008 (JP) 2008-157594

(51) Int. Cl. H01L 21/336

(52) U.S. Cl. 438/270; 257/E21.41

(57) ABSTRACT

A manufacturing method of a SiC device includes: forming a drift layer on a substrate having an orientation tilted from a predetermined orientation with an offset angle; obliquely implanting a second type impurity with a mask on the drift layer so that a deep layer is formed in the drift layer, wherein the impurity is implanted to cancel the offset angle; forming a base region on the deep layer and the drift layer; implanting a first type impurity on the base region so that a high impurity source region is formed; forming a trench having a bottom shallower than the deep layer on the source region to reach the drift layer; forming a gate electrode in the trench via a gate insulation film; forming a source electrode on the source region and the base region; and forming a drain electrode on the substrate.

### CROSS REFERENCE TO RELATED APPLICATION

This application is based on Japanese Patent Application No. 2008-157594 filed on Jun. 17, 2008, the disclosure of which is incorporated herein by reference.

### FIELD OF THE INVENTION

The present invention relates to a method for manufacturing a silicon carbide semiconductor device having a trench gate structure.

### BACKGROUND OF THE INVENTION

Recently, silicon carbide is well known as material for a power device having high electric field breakdown strength. Since a SiC semiconductor device has high electric field breakdown strength, the device can control large current. Accordingly, it is expected to apply the SiC semiconductor device to motor control for a motor in a hybrid vehicle.

In the device, a channel density is increased so as to flow the large current. Here, in a silicon transistor, a trench gate type MOSFET is used for a large current device. The SiC semiconductor device may have trench gate structure. However, when the SiC device has the trench gate structure, a difficulty may arise. Specifically, since the electric field breakdown strength of the SiC is ten times larger than that of Si, a voltage to be applied to the SiC semiconductor device is ten times larger than a voltage to be applied to a Si semiconductor device. Accordingly, an electric field applied to a gate insulation film formed in a trench of the SiC device is ten times larger than that of the Si device. Thus, the gate insulation film at a corner of the trench may be damaged. The inventors calculate the electric field concentration in the gate insulation film in the trench by simulation. When a voltage of 650V is applied to a drain of the device, an electric field of 4.9 MV/cm is concentrated at the gate insulation film in the trench. To use the device actually, it is necessary to reduce the electric field concentration at the insulation film to be equal to or smaller than 3 MV/cm. More specifically, in view of reliability for using the device for a long time, it is necessary to reduce the electric field concentration to be equal to or smaller than 2 MV/cm.

In view of the above difficulty, a SiC semiconductor device is proposed in JP-A-H09-199724 corresponding to U.S. Pat. No. 6,133,587. In the device, a bottom portion of a trench gate is thicker than a sidewall portion of the trench gate so that electric field concentration at the bottom portion is reduced. Specifically, a trench gate structure having a (1120)-face is formed with using a 4H-SiC substrate having a c-face, i.e., a (000-1)-face. In this case, the sidewall of the trench has an a-face, and the bottom of the trench has the c-face. When a gate insulation film is formed in the trench by a thermal oxidation method, the thickness of the oxide film on the bottom of the trench is five times larger than that on the sidewall of the trench since the oxidation rate of the c-face is five times larger than that of the a-face. Thus, the electric field concentration at the bottom of the trench is reduced.

However, when the thickness of the gate insulation film on the bottom of the trench is large, for example, when the thickness of the insulation film on the trench bottom is 200 nm, the thickness of the insulation film on the trench sidewall is 40 nm, and a voltage of 650V is applied to a drain, the electric field concentration in the gate insulation film of the trench is calculated to be 3.9 MV/cm by a simulation method. However, the concentration is not sufficiently reduced, and thereby, it is necessary to reduce the electric field concentration much more.

### SUMMARY OF THE INVENTION

In view of the above-described problem, it is an object of the present disclosure to provide a method for manufacturing a silicon carbide semiconductor device having a trench gate structure.

According to a first aspect of the present disclosure, a method for manufacturing a SiC semiconductor device includes: forming a drift layer made of SiC and having a first conductive type on a first side of a substrate made of SiC and having one of the first conductive type and a second conductive type, wherein the substrate has a face orientation tilted from a predetermined face orientation with a predetermined offset angle, and the drift layer has a face orientation corresponding to the face orientation of the substrate; forming a mask on a surface of the drift layer, obliquely implanting a second conductive type impurity with using the mask on the drift layer, and activating the second conductive type impurity so that a deep layer having the second conductive type is formed in the drift layer; forming a base region made of SiC and having the second conductive type on the deep layer and the drift layer; implanting a first conductive type impurity on a part of the base region so that a source region made of SiC and having the first conductive type is formed, wherein the source region has an impurity concentration higher than the drift layer; forming a trench on a surface of the source region to penetrate the source region and the base region and to reach the drift layer, wherein the trench has a bottom, which is shallower than a bottom of the deep layer; forming a channel layer made of SiC and having the first conductive type in the trench; forming a gate insulation film on a surface of the channel layer in the trench; forming a gate electrode on the gate insulation film in the trench; forming a source electrode on the source region and the base region so that the source electrode is electrically coupled with the source region and the base region; and forming a drain electrode on a second side of the substrate. In the obliquely implanting the second conductive type impurity, the impurity is implanted in a direction where a difference between the direction of implantation and a normal line of the predetermined face orientation is reduced.

In the above method, the deep layer is formed at a deep position, and therefore, a gap between the bottom of the deep layer and a bottom of the trench can be increased. A process window for forming the trench is improved.

According to a second aspect of the present disclosure, a method for manufacturing a SiC semiconductor device includes: forming a drift layer made of SiC and having a first conductive type on a first side of a substrate made of SiC and having one of the first conductive type and a second conductive type, wherein the substrate has a face orientation tilted from a predetermined face orientation with a predetermined offset angle, and the drift layer has a face orientation corresponding to the face orientation of the substrate; forming a current dispersion layer having the first conductive type on the drift layer, wherein the current dispersion layer has an impurity concentration higher than the drift layer, wherein the current dispersion layer has a face orientation corresponding to the face orientation of the substrate; forming a mask on a surface of the current dispersion layer, obliquely implanting a second conductive type impurity with using the mask on the current dispersion layer, and activating the second conductive type impurity so that a deep layer having the second conductive type is formed in the current dispersion layer and the drift layer; forming a base region made of SiC and having the second conductive type on the deep layer and the current dispersion layer; implanting a first conductive type impurity on a part of the base region so that a source region made of SiC and having the first conductive type is formed, wherein the source region has an impurity concentration higher than the drift layer; forming a trench on a surface of the source region to penetrate the source region and the base region and to reach the current dispersion layer or the drift layer, wherein the trench has a bottom, which is shallower than a bottom of the deep layer; forming a channel layer having the first conductive type in the trench; forming a gate insulation film on a surface of the channel layer in the trench; forming a gate electrode on the gate insulation film in the trench; forming a source electrode on the source region and the base region so that the source electrode is electrically coupled with the source region and the base region; and forming a drain electrode on a second side of the substrate. In the obliquely implanting the second conductive type impurity, the impurity is implanted in a direction where a difference between the direction of implantation and a normal line of the predetermined face orientation is reduced.

In the above method, the deep layer is formed at a deep position, and therefore, a gap between the bottom of the deep layer and a bottom of the trench can be increased. A process window for forming the trench is improved.

According to a third aspect of the present disclosure, a method for manufacturing a SiC semiconductor device includes: forming a drift layer made of SiC and having a first conductive type on a first side of a substrate made of SiC and having one of the first conductive type and a second conductive type, wherein the substrate has a face orientation tilted from a predetermined face orientation with a predetermined offset angle, and the drift layer has a face orientation corresponding to the face orientation of the substrate; forming a mask on a surface of the drift layer, obliquely implanting a second conductive type impurity with using the mask on the drift layer, and activating the second conductive type impurity so that a deep layer having the second conductive type is formed in the drift layer; forming a base region made of SiC and having the second conductive type on the deep layer and the drift layer; implanting a first conductive type impurity on a part of the base region so that a source region made of SiC and having the first conductive type is formed, wherein the source region has an impurity concentration higher than the drift layer; forming a trench on a surface of the source region to penetrate the source region and the base region and to reach the drift layer; wherein the trench has a bottom, which is shallower than a bottom of the deep layer; forming a gate insulation film on an inner wall of the trench; forming a gate electrode on the gate insulation film in the trench; forming a source electrode on the source region and the base region so that the source electrode is electrically coupled with the source region and the base region; and forming a drain electrode on a second side of the substrate. In the obliquely implanting the second conductive type impurity, the impurity is implanted in a direction where a difference between the direction of implantation and a normal line of the predetermined face orientation is reduced.

In the above method, the deep layer is formed at a deep position, and therefore, a gap between the bottom of the deep layer and a bottom of the trench can be increased. A process window for forming the trench is improved.

According to a fourth aspect of the present disclosure, a method for manufacturing a SiC semiconductor device includes: forming a drift layer made of SiC and having a first conductive type on a first side of a substrate made of SiC and having one of the first conductive type and a second conductive type, wherein the substrate has a face orientation tilted from a predetermined face orientation with a predetermined offset angle, and the drift layer has a face orientation corresponding to the face orientation of the substrate; forming a current dispersion layer having the first conductive type on the drift layer, wherein the current dispersion layer has an impurity concentration higher than the drift layer, wherein the current dispersion layer has a face orientation corresponding to the face orientation of the substrate; forming a mask on a surface of the current dispersion layer, obliquely implanting a second conductive type impurity with using the mask on the current dispersion layer, and activating the second conductive type impurity so that a deep layer having the second conductive type is formed in the current dispersion layer and the drift layer; forming a base region made of SiC and having the second conductive type on the deep layer and the current dispersion layer; implanting a first conductive type impurity on a part of the base region so that a source region made of SiC and having the first conductive type is formed, wherein the source region has an impurity concentration higher than the drift layer; forming a trench on a surface of the source region to penetrate the source region and the base region and to reach the current dispersion layer or the drift layer, wherein the trench has a bottom, which is shallower than a bottom of the deep layer; forming a gate insulation film on an inner wall of the trench; forming a gate electrode on the gate insulation film in the trench; forming a source electrode on the source region and the base region so that the source electrode is electrically coupled with the source region and the base region; and forming a drain electrode on a second side of the substrate. In the obliquely implanting the second conductive type impurity, the impurity is implanted in a direction where a difference between the direction of implantation and a normal line of the predetermined face orientation is reduced.

In the above method, the deep layer is formed at a deep position, and therefore, a gap between the bottom of the deep layer and a bottom of the trench can be increased. A process window for forming the trench is improved.

### BRIEF DESCRIPTION OF THE DRAWINGS

The above and other objects, features and advantages of the present invention will become more apparent from the following detailed description made with reference to the accompanying drawings. In the drawings:

FIG. 1 is a diagram showing a trench gate type MOSFET according to a first embodiment;

FIG. 2A is a cross sectional view showing the device taken along line IIA-IIA in FIG. 1, FIG. 2B is a cross sectional view showing the device taken along line IIB-IIB in FIG. 1, FIG. 2C is a cross sectional view showing the device taken along line IIC-IIC in FIG. 1, and FIG. 2D is a cross sectional view showing the device taken along line IID-IID in FIG. 1;

FIGS. 3A to 3F are diagrams showing a manufacturing method of the MOSFET in FIG. 1;

FIGS. 4A to 4F are diagrams showing the manufacturing method of the MOSFET in FIG. 1;

FIGS. 5A and 5B are diagrams showing a relationship among a surface of a drift layer, an offset angle and an ion implantation angle;

FIGS. 6A to 6D are diagrams showing a depth profile between an implantation depth and an impurity concentration;

FIG. 7 is a diagram showing a trench gate type MOSFET according to a second embodiment;

FIG. 8A is a cross sectional view showing the device taken along line VIIIA-VIIIA in FIG. 7, FIG. 8B is a cross sectional view showing the device taken along line VIIIB-VIIIB in FIG. 7, FIG. 8C is a cross sectional view showing the device taken along line VIIIC-VIIIC in FIG. 7, and FIG. 8D is a cross sectional view showing the device taken along line VIIID-VIIID in FIG. 7;

FIGS. 9A to 9F are diagrams showing a manufacturing method of the MOSFET in FIG. 7;

FIGS. 10A to 10F are diagrams showing the manufacturing method of the MOSFET in FIG. 7;

FIG. 11 is a diagram showing a trench gate type MOSFET according to a third embodiment;

FIG. 12A is a cross sectional view showing the device taken along line XIIA-XIIA in FIG. 11, FIG. 12B is a cross sectional view showing the device taken along line XIIB-XIIB in FIG. 11, FIG. 12C is a cross sectional view showing the device taken along line XIIC-XIIC in FIG. 11, and FIG. 12D is a cross sectional view showing the device taken along line XIID-XIID in FIG. 11;

FIGS. 13A to 13F are diagrams showing a manufacturing method of the MOSFET in FIG. 11;

FIGS. 14A to 14F are diagrams showing the manufacturing method of the MOSFET in FIG. 11;

FIG. 15 is a diagram showing a trench gate type MOSFET according to a fourth embodiment; and

FIGS. 16A and 16B are diagrams showing a vertical MOSFET according to a related art.

### DETAILED DESCRIPTION OF THE PREFERRED EMBODIMENTS

The present inventors have studied about a SiC semiconductor device having a trench gate structure. Specifically, to reduce an electric field concentration at a gate insulation film in a trench, a P type deep layer is formed such that the deep layer extends along with a longitudinal direction of the trench gate, and the deep layer is deeper than the bottom of the trench gate. Further, the deep layer is arranged under a P⁺ type contact region, which electrically connects a P type base region and a source electrode. The deep layer is disposed opposite to the trench gate with a N⁺ type source region and a P type base region. The device is disclosed in a Japanese Patent Application No. 2007-288545, which is filed by the present inventors and corresponds to U.S. patent application Ser. No. 12/289,624.

In the device, a step for forming the trench gate is independent from a step for forming the deep layer. Thus, it is difficult to align a position of the trench gate and a position of the deep layer. Thus, a distance between the deep layer and the sidewall of the trench may be varied. In view of this point, the present inventors have studied about a SiC semiconductor device, which is disclosed in Japanese Patent Application No. 2008-31704 filed by the present inventors and corresponding to U.S. patent application Ser. No. 12/379,076. In this case, a P type deep layer extends along with a direction perpendicular to a portion to be a channel, which is arranged on a sidewall of a trench.

In the above devices, an interface between the deep layer and a N− type drift layer provides a PN junction. A depletion layer from the PN junction expands toward the drift layer. Thus, a high voltage caused by the drain voltage is not substantially applied to the gate insulation film. Thus, the electric field concentration at the gate insulation film at the bottom of the trench is reduced so that the gate oxide film is not damaged.

Further, in the device, the longitudinal direction of the trench is perpendicular to the longitudinal direction of the deep layer. Thus, even if a mask for forming the trench and a mask for forming the deep layer are not aligned with high accuracy, variation of positional relationship between the trench and the deep layer does not affect characteristics of the device.

In the above case, a N type current dispersion layer is arranged between the drift layer and the base layer. To form the current dispersion layer, the current flowing through the channel is dispersed in a wide area so that the dispersed current flows in the drift layer. Thus, the on-state resistance in the device is reduced.

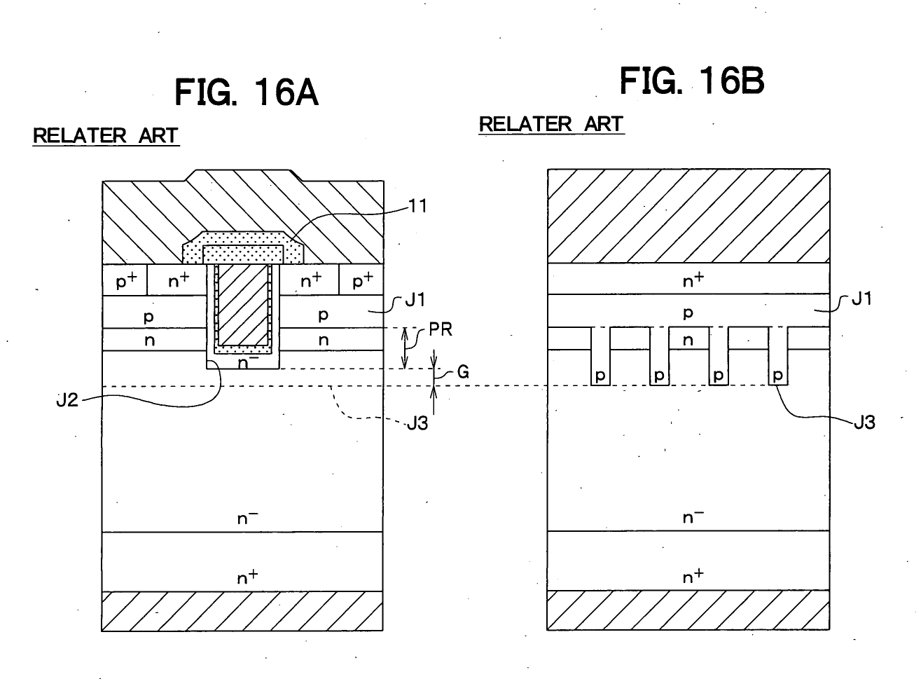

In the SiC semiconductor device, it is preferable to have the following relationship in view of the characteristics of the device. The relationship will be explained as follow with reference to FIGS. 16 A and 16B. FIGS. 16A and 16B show a vertical MOSFET having a trench gate structure.

FIG. 16A is a cross section of the SiC semiconductor device taken along a line perpendicular to the longitudinal direction of the trench gate, and FIG. 16B is a cross section of the device taken along a line parallel to the longitudinal direction of the trench gate.

In the device, a protrusion amount PR of the bottom of the trench, i.e., the protrusion amount PR of the trench J2 from the bottom of the P type base region J1 is large, for example, equal to or larger than 0.5 μm so that the on-state current is increased. In view of the breakdown voltage of the device, it is preferred to enlarge a gap G between the bottom of the trench J2 and the bottom of the deep layer J3. Thus, it is preferred that the bottom of the trench J2 becomes deeper, and the deep layer J3 becomes deeper.

In general, when the deep layer J3 is formed by an ion implantation method, an ion impurity is implanted in SiC material with a depth of about 0.7 μm. Accordingly, the gap G between the bottom of the trench J2 and the bottom of the deep layer J3 becomes smaller. For example, when the depth of the deep layer J3 is 0.7 μm, and the protrusion amount PR of the trench J2 is 0.5 μm, the gap G is set to be 0.2 μm, which is not sufficiently large. In this case, a difference between the bottom of the deep layer J3 and the bottom of the trench J2 is small, so that the electric field relaxation effect for reducing the electric field concentration becomes smaller. Further, when the trench J2 is much deeper, the trench J2 may be deeper than the deep layer J3. Accordingly, it is difficult to control the depth of the trench J2. Thus, a process window in a step for forming the trench J2 is not set to be larger.

Here, the depth of the deep layer is determined by the energy of the ion implantation step. Thus, when the implantation energy is high, the depth of the deep layer becomes large. In case of the SiC material, huge energy is required to form the deep layer J3 at a predetermined depth. Thus, an ion implantation equipment for performing the implantation with high energy is required. In view of a manufacturing cost, alternative method is required.

Thus, in a manufacturing method of the SiC semiconductor device having the trench gate structure with the deep layer deeper than the trench, it is required to set the process window in the step of forming the trench to be larger.

### First Embodiment

In view of the above requirement, a SiC semiconductor device according to a first embodiment is proposed. The device is an accumulation type trench gate MOSFET.

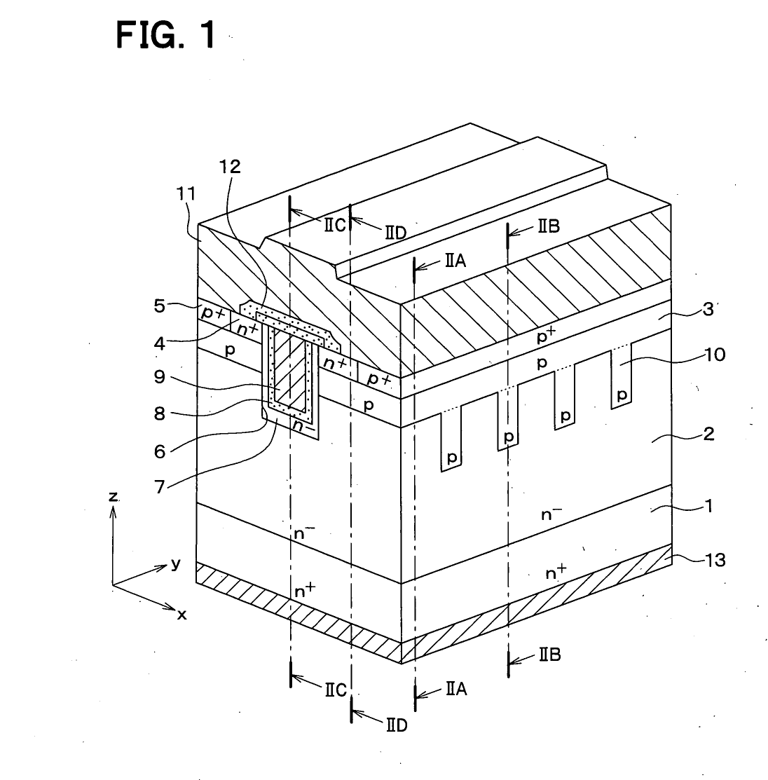

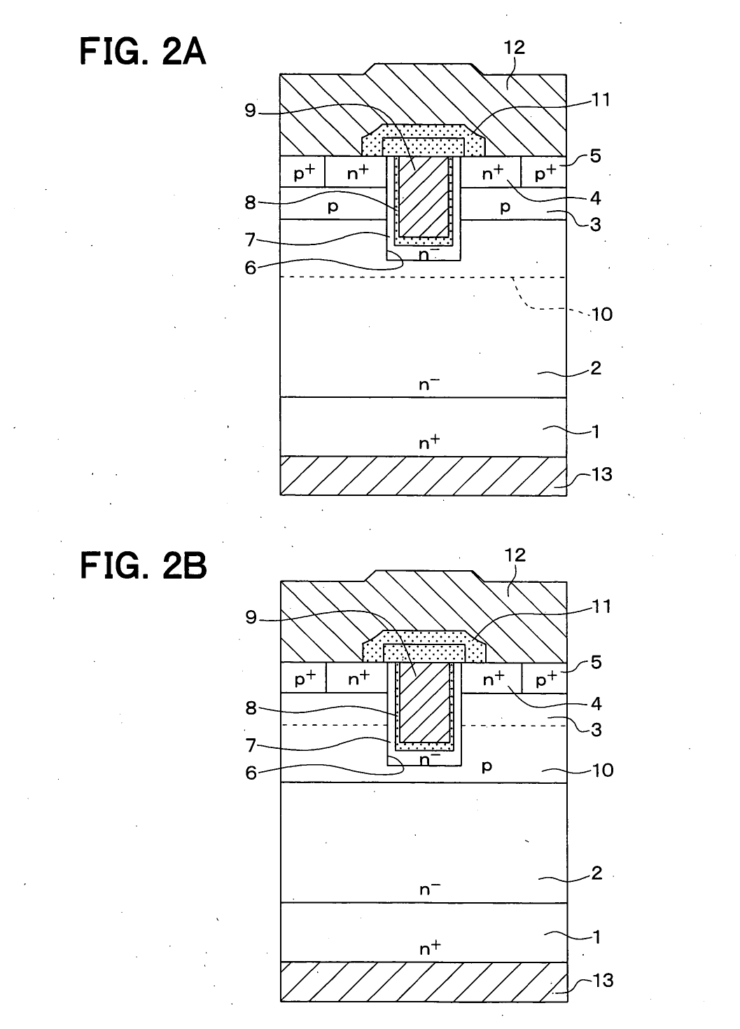

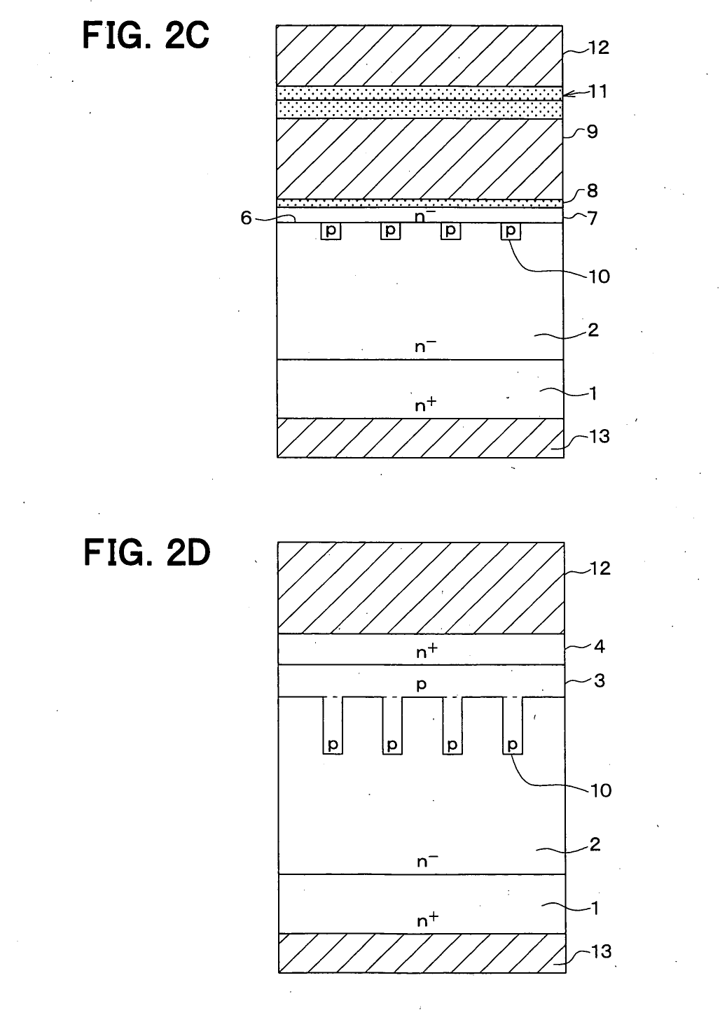

FIG. 1 shows a part of a MOSFET having a trench gate structure. The part corresponds to one cell in the MOSFET. Although FIG. 1 shows the one cell in the MOSFET, the MOSFET includes multiple cells, which are arranged adjacently along with a line. FIG. 2A shows a cross section of the MOSFET taken along line IIA-IIA in FIG. 1. Specifically, the cross section of FIG. 2A is taken along a X-Z plane passing through the line IIA-IIA in FIG. 1. FIG. 2B shows a cross section of the MOSFET taken along line IIB-IIB in FIG. 1. Specifically, the cross section of FIG. 2B is taken along a X-Z plane passing through the line IIB-IIB in FIG. 1. FIG. 2C shows a cross section of the MOSFET taken along line IIC-IIC in FIG. 1. Specifically, the cross section of FIG. 2C is taken along a Y-Z plane passing through the line IIC-IIC in FIG. 1. FIG. 2D shows a cross section of the MOSFET taken along line IID-IID in FIG. 1. Specifically, the cross section of FIG. 2D is taken along a Y-Z plane passing through the line IID-IID in FIG. 1.

The MOSFET includes a N⁺ type substrate 1 as a semiconductor substrate made of SiC. The substrate 1 has a N type impurity such as phosphorus with an impurity concentration of, for example, 1.0×10¹⁹/cm³. The thickness of the substrate 1 is about 300 μm. The substrate has a surface, which inclines at a predetermined angle as an offset angle such as two to eight degrees to a predetermined face orientation such as a c-face, i.e., a (000-1)-face.

A N− type drift layer 2 is formed on the surface of the substrate 1. The drift layer 1 is made of SiC and has a N⁻ type impurity such as phosphorus with an impurity concentration, which is lower than a predetermined value. For example, the impurity concentration of the drift layer is 3.0×10¹⁵/cm³ to 7.0×10¹⁵/cm³, and the thickness of the drift layer 2 is about 10 μm to 15 μm. The impurity concentration in the drift layer 2 may be constant in a depth direction. Alternatively, the impurity concentration in the drift layer 2 is gradually varied. For example, the impurity concentration in a part of the drift layer 2 near the substrate 1 is larger than that in another part of the drift layer 2 far from the substrate 1. For example, the impurity concentration of the part of the drift layer 2 in a range from the surface of the substrate 1 to a depth of 3 μm to 5 μm is larger by a predetermined value such as 2.0×10¹⁵/cm³ than the impurity concentration of other parts of the drift layer 2. In this case, since the inner resistance of the drift layer 2 is reduced, the on-state resistance of the device is reduced.

A P type base region 3 is formed in a surface portion of the drift layer 2. A N⁺ type source region 4 and a P⁺ type body layer 5 as a contact layer are formed over the base region 3.

The base region 3 has a P type impurity such as boron and aluminum with an impurity concentration of 5.0×10¹⁶/cm³ to 2.0×10¹⁹/cm³. The thickness of the base region 3 is about 2.0 μm. The source region 4 has the thickness of 0.3 μm and a N type impurity such as phosphorus with a surface impurity concentration in a surface portion of the source region 4 of, for example, 1.0×10²¹/cm³. The body layer 5 has the thickness of 0.3 μm and a P type impurity such as boron and aluminum with a surface impurity concentration in a surface portion of the body layer 5 of, for example, 1.0×10²¹/cm³. The source region 4 is disposed on both sides of the trench gate structure. The body layer 5 is arranged opposite to the trench gate structure via the source region 4 therebetween.

A trench 6 is formed such that the trench penetrates the base region 3 and the source region 4 and reaches the drift layer 2. The width of the trench 6 is in a range between 1.4 μm and 2.0 μm. The depth of the trench 6 is equal to or larger than 2.0 μm. For example, the depth of the trench 6 is 2.5 μm. A protruding amount of the trench 6 from the bottom of the base region 3 is equal to or larger than 0.5 μm.

The base region 3 and the source region 4 are arranged to contact the sidewall of the trench 6. A N type channel layer 7 is formed on an inner wall of the trench 6. The channel layer 7 has a N type impurity such as phosphorus with an impurity concentration of, for example, 1.0×10¹⁶/cm³. The channel layer 7 provides a channel region. The thickness of the channel layer 7 is set to provide a normally off-type device. For example, the thickness of the channel layer 7 on the bottom of the trench 6 is in a range between 0.3 μm and 1.0 μm. The thickness of the channel layer 7 on the sidewall of the trench 6 is in a range between 0.1 μm and 0.3 μm.

A gate oxide film 8 covers the surface of the channel layer 7. A gate electrode 9 is formed in the trench 6 via the gate oxide film 8. The gate electrode 9 is made of doped poly silicon. Thus, the gate electrode 9 is embedded in the trench 6. The gate oxide film 8 is formed such that the surface of the channel layer 7 is thermally oxidized. The thickness of the gate oxide film 8 on the bottom of the trench 6 is about 100 nm, and the thickness of the gate oxide film 8 on the sidewall of the trench 6 is about 100 nm.

Thus, the trench gate structure is formed in the device. The trench gate structure extends along with the Y direction as a longitudinal direction in FIG. 1. Multiple trench gate structures are aligned in parallel to the X direction in FIG. 1. The source region 4 and the body layer 5 also extend along with the longitudinal direction of the trench gate structure.

A P type deep layer 10 is formed in the drift layer 2 under the base region 3. The deep layer 10 extends along with a direction (i.e., the X direction in FIG. 1) perpendicular to the longitudinal direction of the trench 6. Here, the X direction provides a normal line of an extending direction of the channel region on the sidewall of the trench 6, and the extending direction of the channel region is the Y direction and the longitudinal direction of the trench 6. The deep layer 10 is deeper than the bottom of the channel layer 7, which is equal to the bottom of the trench 6. The depth of the deep layer 10 is, for example, 2.6 μm to 3.0 μm from the surface of the drift layer 2. Thus, the depth of the deep layer 10 is, for example, 0.6 μm to 1.0 μm from the bottom of the base region 3. The width of the deep layer 10 along with the Y direction is in a range between 0.6 μm to 1.0 μm. The impurity concentration of the P type impurity such as boron and aluminum in the deep layer 10 is, for example, 1.0×10¹⁷/cm³ to 1.0×10¹⁹/cm³. The impurity concentration in the deep layer 10 has a concentration gradient so that the impurity concentration in the deep layer 10 becomes lower as the depth from the bottom of the base region 3 becomes deeper. The device includes multiple deep layers 10, which are aligned along with the longitudinal direction of the trench gate structure. A distance between adjacent two deep layers 10 is, for example, 2 μm to 3 μm.

A source electrode 11 is formed on the surface of the source region 4 and the surface of the body layer 5. A gate wiring (not shown) is formed on the surface of the gate electrode 9. The source electrode 11 and the gate wiring are made of multiple metal materials such as nickel and aluminum. At least a part of the source electrode 11 and a part of the gate wiring that contact N type SiC material (i.e., the source region 4 and the gate electrode 9 in a case where the gate electrode 9 includes N type impurity doped therein) is made of metal material capable of contacting the N type SiC material with an ohmic contact. At least a part of the source electrode 11 and a part of the gate wiring that contact P type SiC material (i.e., the body layer 5 and the gate electrode 9 in a case where the gate electrode 9 includes P type impurity doped therein) is made of metal material capable of contacting the P type SiC material with an ohmic contact. The source electrode 11 and the gate wiring are formed on an interlayer insulation film 12 so that the source electrode 11 and the gate wiring are electrically isolated from each other. The source electrode 11 is electrically connected to the source region 4 and the body layer 5 via a contact hole in the interlayer insulation film 12. The gate wiring is electrically connected to the gate electrode 9 via a contact hole in the interlayer insulation film 12.

The drain electrode 13 is formed on the backside of the substrate 1 is that the drain electrode 13 is electrically connected to the substrate 1. Thus, the accumulation type n channel MOSFET having the trench gate structure is manufactured.

The MOSFET functions as follows.

Before the gate voltage is applied to the gate electrode 9, the device performs as if a negative voltage of −3V is applied to the base region 3 even when the null voltage is applied to the source electrode 11. since the SiC material, has an inherent potential of about 3V when the impurity concentration in the SiC material is high, i.e., when the impurity concentration in the SiC material is 1.0×10¹⁹/cm³. Even when the source electrode 11 is at 0V, the base region 3 behaves to be applied with −3V. Accordingly, the depletion layer expands from the base region 3. A region around the base region 3 functions as an insulator. Thus, even when a positive voltage is applied to the drain electrode 13, the channel layer 7 functions as an insulator. In this case, an electron does not reach the channel layer 7, and the current does not flow between the source electrode 11 and the drain electrode 13.

Next, when the device turns off, the depletion layer expands from an interface between the base region 3 and the drift layer 2 including the channel layer 7 since a reverse bias is applied to the drain electrode 13 even when a voltage is applied to the drain electrode 13. Here, when the device is in an off state, the gate voltage is 0V, the drain voltage is 650V, and the source voltage is 0V. Since the impurity concentration of the base region 3 is much higher than the drift layer 2, the depletion layer almost expands in the drift layer side. For example, when the impurity concentration of the base region 3 is ten times larger than the drift layer 2, the depletion layer expands by 0.7 μm on the base region side from the interface, and the depletion layer expands by 7.0 μm on the drift layer side from the interface. Since the thickness of the base region 3 is 2.0 μm, which is larger than the expanding amount of the depletion layer, punch through phenomenon does not occur in the device. Since the depletion layer expands larger than a case where the drain voltage is 0V, a region behaving as an insulator expands much more. Thus, the current does not flow between the source electrode 11 and the drain electrode 13.

Since the gate voltage is 0V, an electric field is applied between the drain and the gate. Accordingly, the electric field concentration occurs at the bottom of the gate oxide film 8. However, since the deep layer 10 is deeper than the trench 6, the depletion layer largely expands from a PN junction between the deep layer 10 and the drift layer 2 toward the drift layer side. A high voltage provided by influence of the drain voltage does not penetrate into the gate oxide film 8. Specifically, when the impurity concentration of the deep layer 10 is higher than the base region 3, the expanding amount of the depletion layer toward the drift layer side becomes large. Thus, it is possible to reduce the electric field concentration at the bottom of the trench 6 in the gate oxide film 8. Thus, the gate oxide film 8 is prevented from being damaged.

When the device turns on, the gate voltage of 20V is applied to the gate electrode 9. Thus, the channel layer 7 functions as an accumulation type channel. Here, when the device turns on, the gate voltage is 20V, the drain voltage is 1V, and the source voltage is 0V. Accordingly, an electron introduced from the source electrode 11 flows from the source region 4 to the drift layer 2 through the channel layer 7. Thus, the current flows between the source electrode 11 and the drain electrode 13.

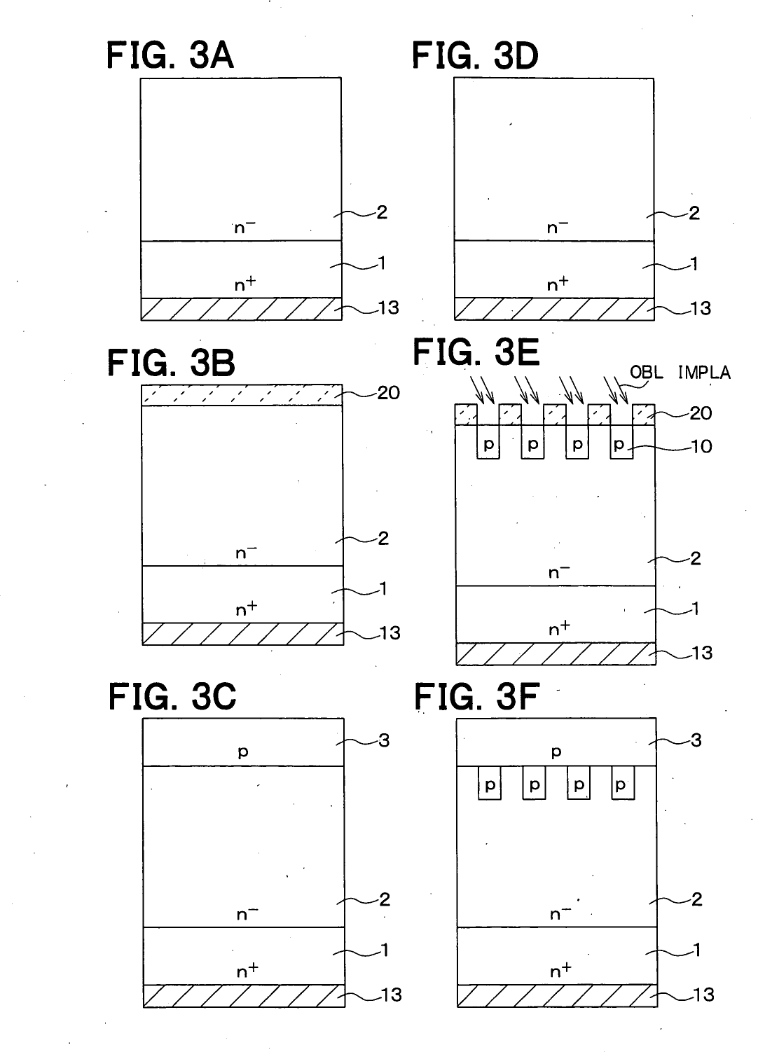

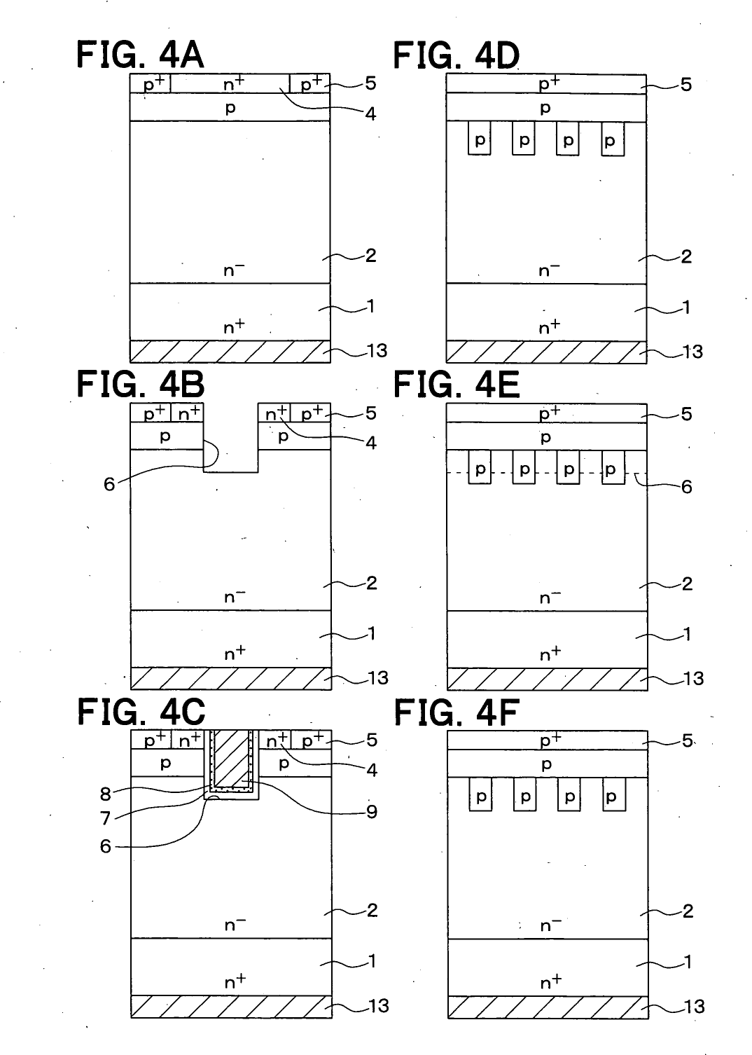

A manufacturing method of the trench gate type MOSFET in FIG. 1 will be explained as follows. FIGS. 3A to 4F shows the manufacturing method. FIGS. 3A to 3C and 4A to 4C are cross sectional views of the device taken along line IIA-IIA passing through a plane in parallel to the X-Z plane. FIGS. 3D to 3F and 4D to 4F are cross sectional views of the device taken along line IID-IID passing through a plane in parallel to the Y-Z plane.

(Step in FIGS. 3A and 3D)

First, the N+ type substrate 1 having the N type impurity such as phosphorus with the impurity concentration of 1.0×10¹⁹/cm³ is prepared. The substrate 1 has the thickness of 300 μm, and the surface of the substrate 1 is tilted at the offset angle such as two to eight degrees from a predetermined face such as the c-face, i.e., the (000-1)-face. The drain electrode 13 is formed on the backside of the substrate 1. Then, the drift layer 2 made of SiC is epitaxially grown on the surface of the substrate 1. The drift layer 2 has the thickness of 15 μm, and the N type impurity concentration of 3.0×10¹⁵/cm³ to 7.0×10¹⁵/cm³. Since the surface of the substrate 1 is inclined at the predetermined offset angle to the predetermined face orientation. Thus, the crystal growth of the drift layer 2 is easily performed. Since the drift layer 2 is epitaxially grown on the substrate 1, the face orientation of the drift layer 2 is inherited from the face orientation of the substrate 1.

(Step in FIGS. 3B and 3E)

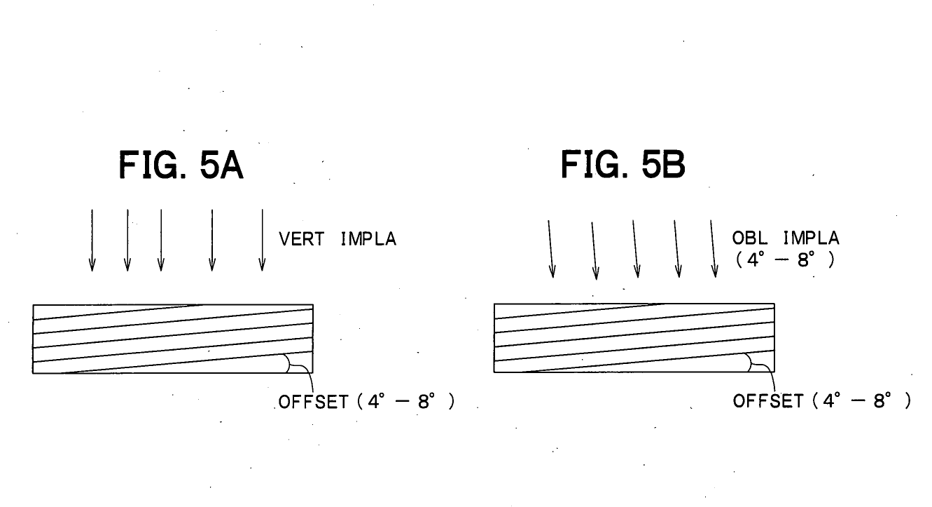

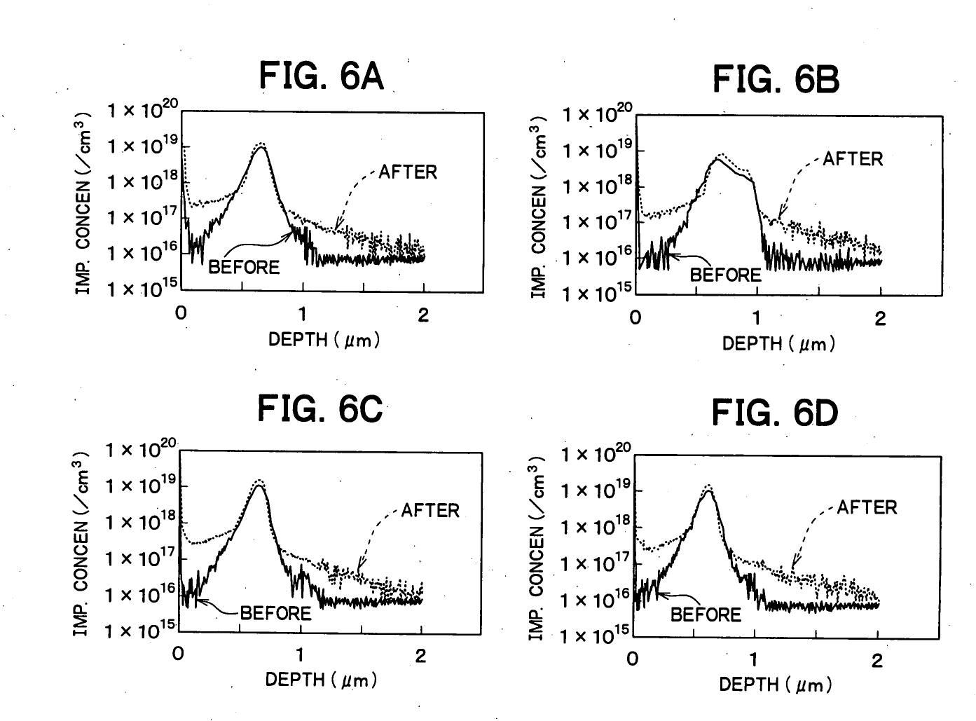

After a mask 20 made of a LTO film is formed on the drift layer 2, the mask 20 is processed in a photo lithography method, so that an opening is formed in the mask 20. The opening corresponds to a deep-layer-to-be-formed region. A P type impurity such as boron and aluminum is implanted through the mask 20. The ion implantation is performed by an oblique ion implantation method. The reason why the oblique ion implantation method is performed will be explained as follows with reference to FIGS. 5A to 6D.

FIGS. 5A and 5B show a relationship between the surface of the drift layer 2, the offset angle and the ion implantation angle. FIG. 5A shows a vertical ion implantation such that the impurity is implanted along with a direction perpendicular to the substrate 1. FIG. 5B shows an oblique ion implantation such that the impurity is implanted along with a direction in parallel to a normal line with respect to the c-face. FIGS. 6A to 6D show a relationship between an impurity concentration and a depth in four different samples having different ion implantation angles and different ion implantation temperatures. FIG. 6A shows the depth profile before and after heat treatment in a case where the ion implantation temperature is 700° C., and the ion is implanted along with the direction perpendicular to the substrate 1. FIG. 6B shows the depth profile before and after heat treatment in a case where the ion implantation temperature is 700° C., and the ion is implanted along with the direction in parallel to the normal line of the c-face. FIG. 6C shows the depth profile before and after heat treatment in a case where the ion implantation temperature is 700° C., and the ion is implanted along with the direction tilted at 16 degrees to the normal line of the c-face. In this case, the ion is implanted along with the direction opposite to the direction in parallel to the normal line of the c-face so that the direction is tilted at 8 degrees to the direction perpendicular to the substrate 1. FIG. 6D shows the depth profile before and after heat treatment in a case where the ion implantation temperature is room temperature, and the ion is implanted along with the direction perpendicular to the substrate 1.

When the case that the ion is implanted along with the direction perpendicular to the substrate 1 is compared with the case that the ion is implanted along with the direction in parallel to the normal line of the c-face, as shown in FIGS. 6A and 6B, in the case shown in FIG. 5B that the ion is implanted along with the direction in parallel to the normal line of the c-face, the impurity concentration is high in a deeper position than the case shown in FIG. 5A that the ion is implanted along with the direction perpendicular to the substrate 1. Since the thermal diffusion is not substantially occurred in the SiC material, the ion implantation in the case shown in FIG. 5B is performed in a deeper position than the case shown in FIG. 5A. Thus, when the offset substrate 1 is used in order to perform the epitaxial growth easily, by performing the oblique ion implantation, the ion implantation is performed at the deeper position. Here, the oblique ion implantation is performed such that the offset angle of the substrate 1 is cancelled so that the ion implantation is performed along with the normal line of the c-face.

In a case shown in FIG. 6C that the ion implantation is performed by tilting the substrate 1 to a direction opposite to a direction for canceling the offset angle, and in a case shown in FIG. 6D that the ion implantation temperature is varied, the depth profiles of the impurity are substantially similar to the depth profile in the case shown in FIG. 6A that the ion implantation is performed vertically to the substrate 1. Thus, the oblique ion implantation is performed so that the impurity is implanted at the deeper position. The oblique ion implantation is performed such that the substrate 1 is inclined to the direction for canceling the offset angle of the substrate 1 and the drift layer 2.

When the above oblique ion implantation is performed, as shown in FIG. 6B, the impurity concentration in the deep layer 10 has a concentration gradient. Specifically, as shown in FIGS. 6A, 6C and 6D, the depth profile of the impurity concentration shows a steep peak with reference to the depth of the ion implantation. The depth profile in FIG. 6B does not show a steep peak, but gradually reduction of the concentration as the depth becomes larger. Accordingly, the concentration distribution of the impurity has the concentration gradient so that the impurity concentration becomes lower as the depth becomes larger.

In this embodiment, the oblique ion implantation is performed so that the deep layer 10 is formed. The ion implantation degree is determined to cancel the offset angle of the substrate 1 and the drift layer 2 so that a difference between the normal line of the c-face and the implantation direction becomes smaller than a case where the ion is implanted in the direction perpendicular to the substrate 1. Thus, a tilt angle from the normal line to the ion implantation direction becomes small. Specifically, the ion implantation direction is set to be in parallel to the normal line of the c-face, i.e., the ion implantation is performed to have the tilt angle equal to the offset angle of the substrate 1 with respect to the direction perpendicular to the substrate 1, so that the oblique ion implantation is performed to cancel the offset angle of the substrate 1 and the drift layer 2. Thus, the ion is implanted at deeper position than a case where the ion is implanted in the direction perpendicular to the substrate 1 so that the deep layer 10 is formed at a deeper position. Further, the impurity concentration in the deep layer 10 becomes smaller as the depth in the deep layer 10 becomes larger.

The P type impurity is implanted by the oblique ion implantation method, and then, the impurity is activated. Thus, the deep layer 10 having the boron or aluminum impurity concentration in a range between 1.0×10¹⁷/cm³ to 1.0×10¹⁹/cm³, and the thickness in a range between 0.6 μm and 1.0 μm, and the width in a range between 0.6 μm and 1.0 μm is formed. Then, the mask 20 is removed.

(Step in FIGS. 3C and 3F)

A P type impurity layer is epitaxially formed on the surface of the drift layer 2. The P type impurity layer has the P type impurity concentration in a range between 5.0×10¹⁶/cm³ and 2.0×10¹⁹/cm³, and the thickness of 2.0 μm. The P type impurity is, for example, aluminum or boron. The P type impurity layer provides the base region 3.

(Step in FIGS. 4A and 4D)

A mask (not shown) made of a LTO (low temperature oxide) film is formed on the base region 3, and the mask is processed in a photo lithography process so that an opening is formed in the mask. The opening corresponds to a source-region-to-be-formed region. Then, a N type impurity such as nitrogen is implanted. Then, the mask is removed, and another mask (not shown) is formed on the base region 3. The other mask is processed in a photo lithography process so that an opening is formed in the other mask. The opening corresponds to a body-layer-to-be-formed region. Then, a P type impurity such as nitrogen is implanted, and the implanted ion is activated. Thus, the source region 4 and the body layer 5 are formed. The source region 4 has the N type impurity concentration or the surface impurity concentration of, for example, phosphorus of 1.0×10²¹/cm³ and the thickness of 0.3 μm. The body layer 5 has the P type impurity concentration or the surface impurity concentration of, for example, boron or aluminum of 1.0×10²¹/cm³ and the thickness of 0.3 μm. Then, the other mask is removed.

(Step in FIGS. 4B and 4E)

An etching mask (not shown) is formed on the base region 3, the source region 4 and the body layer 5′. An opening is formed in the etching mask. The opening corresponds to a trench-to-be-formed region. Anisotropic etching process with using the etching mask is performed. Then, an isotropic etching process and/or a sacrifice oxidation process are performed if necessary. Thus, the trench 6 is formed. Then, the etching mask is removed.

(Step in FIGS. 4C and 4F)

The channel layer 7 is epitaxially formed in the trench 6 and on the whole surface of the substrate 1. The channel layer 7 has the N type impurity concentration of, for example, 1.0×10¹⁶/cm³. The N type impurity is phosphorus or the like. Since the epitaxial growth depends on a face orientation, the channel layer 7 has the thickness on the bottom of the trench 6, which is larger than the thickness on the sidewall of the trench 6. Then, a part of the channel layer 7 disposed on the base region 3, the source region 4 and the body layer 5 is removed since the part of the channel layer 7 is an unnecessary portion. Then, the gate oxide film 8 is formed in a gate oxide film forming step. Specifically, the gate oxide film 8 is formed by a pyrogenic oxidation method under wet atmosphere so that thermal gate oxidization is performed.

Then, a poly silicon layer having a N type impurity is formed on the surface of the gate oxide film 8 at 600° C. The thickness of the poly silicon layer is 440 nm. Then, an etch back process or the like is performed, so that the gate electrode 9 is embedded in the trench 6 via the gate oxide film 8. Thus, the gate oxide film 8 and the gate electrode 9 remain in the trench 6.

The interlayer insulation film 12 is deposited, and then, the interlayer insulation film 12 is patterned so that the contact hole for connecting to the source region 4 and the body layer 5 is formed in the insulation film 12. Further, the contact hole for connecting to the gate electrode 9 is formed in another part of the insulation film 12. Then, electrode material is formed to fill the contact hole, and the electrode material film is pattered so that the source electrode 11 and the gate wiring are formed. Thus, the MOSFET shown inn FIG. 1 is completed.

In the above manufacturing method, when the deep layer 10 is formed, the P type impurity is implanted by the oblique ion implantation method so that the offset angle of the substrate 1 is cancelled. Accordingly, the deep layer 10 is formed at the deep position. The gap G from the deep layer 10 to the bottom of the trench 6 becomes large. Thus, the process window in case of forming the trench 6 becomes large.

The oblique ion implantation method provides the structure such that the impurity concentration in the deep layer 10 becomes lower as the depth in the deep layer 10 becomes deeper. This provides the following effects.

To improve the breakdown voltage of the device, it is preferred that the distance between the bottom of the deep layer 10 and the bottom of the trench 6 is increased. When the impurity concentration of the deep layer 10 is high, the electric field relaxation effect at the bottom of the trench gate becomes high so that the breakdown voltage is much improved. To increase the on-state current, it is preferred that the depth of the trench 6 is reduced. Further, to increase the on-state current, it is preferred that the impurity concentration in the deep layer 10 is reduced. Accordingly, the breakdown voltage and the on-state current have a trade-off relationship. To improve the trade-off relationship, the impurity concentration in a deeper part of the deep layer 10 is gradually reduced so that the deeper part of the deep layer 10 has a concentration gradient.

When the ion is implanted in the direction perpendicular to the substrate 1 in order to form the deep layer 10, the depth profile of the P type impurity in the deep layer 10 has a sharp peak with reference-to the depth direction. In this case, the impurity concentration in the deep layer 10 is rapidly reduced from the bottom of the deep layer 10. Accordingly, the trade-off relationship between the breakdown voltage improvement and the on-state current improvement is not improved.

In this embodiment, since the oblique ion implantation is performed, the impurity concentration in the deep layer 10 is reduced gradually as the depth of the deep layer 10 becomes larger. Thus, the trade-off relationship between the breakdown voltage improvement and the on-state current improvement is improved.

In another manufacturing method, a trench may be formed on a deep-layer-to-be-formed region, and then, the P type layer may be embedded in the trench. Thus, the deep layer 10 is formed. In this case, after the P type layer is embedded in the trench, it is necessary to perform a flattening process. However, in the flattening process, a crystal defect may be generated in the device. In the present embodiment, the deep layer 10 is formed by the ion implantation method. Thus, the generation of the crystal defect is reduced.

Alternatively, the ion may be implanted on the surface of the base layer 3 so that the deep layer 10 is formed. In the present embodiment, the ion is implanted on the surface of the drift layer 2 so that the deep layer 10 is formed. Accordingly, the deep layer 10 is formed without high energy and high speed ion implantation. Therefore, no crystal defect caused by the high speed ion implantation is generated.

Further, when the longitudinal direction of the trench 6 and the longitudinal direction of the deep layer 10 are in parallel to each other, if a distance among the trench 6 and the deep layer 10 is varied, the variation may affect the characteristics of the device. In this case, it is important to align a position of a mask for forming the trench 6 and a position of another mask for forming the deep layer 10. However, since the alignment of the position of the mask necessarily has an error, the influence of the alignment error of the mask on the device characteristics is not completely eliminated. On the other hand, in the present embodiment, since the longitudinal direction of the trench 6 is perpendicular to the longitudinal direction of the deep layer 10, the mask alignment error does not affect the device characteristics. Thus, the product variation is reduced, and the yielding ratio of the manufacturing process is improved. Accordingly, the above manufacturing method of the SiC semiconductor device provides to reduce the variation of the product characteristics and to improve the yielding ratio.

### Second Embodiment

In a SiC semiconductor device according to a second embodiment, an on-state resistance is reduced.

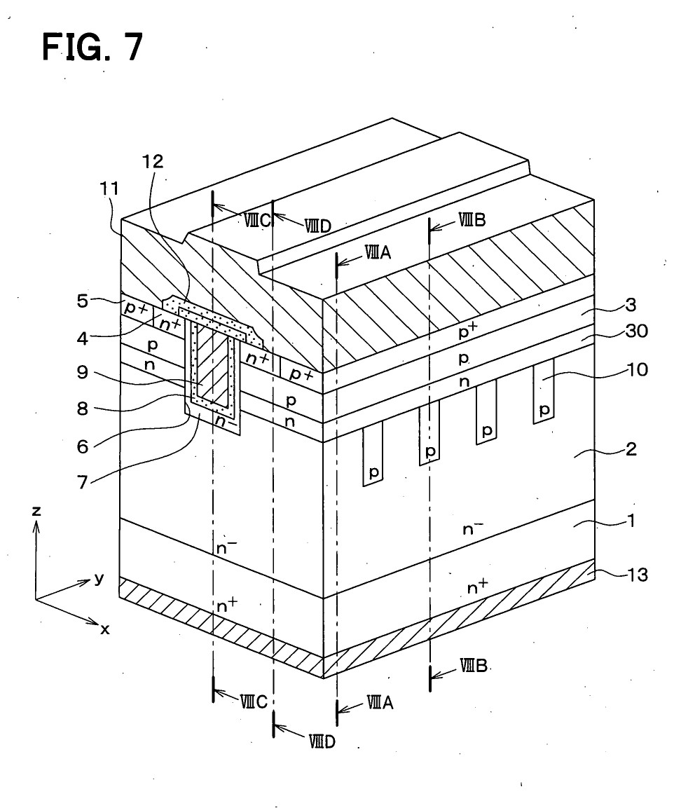

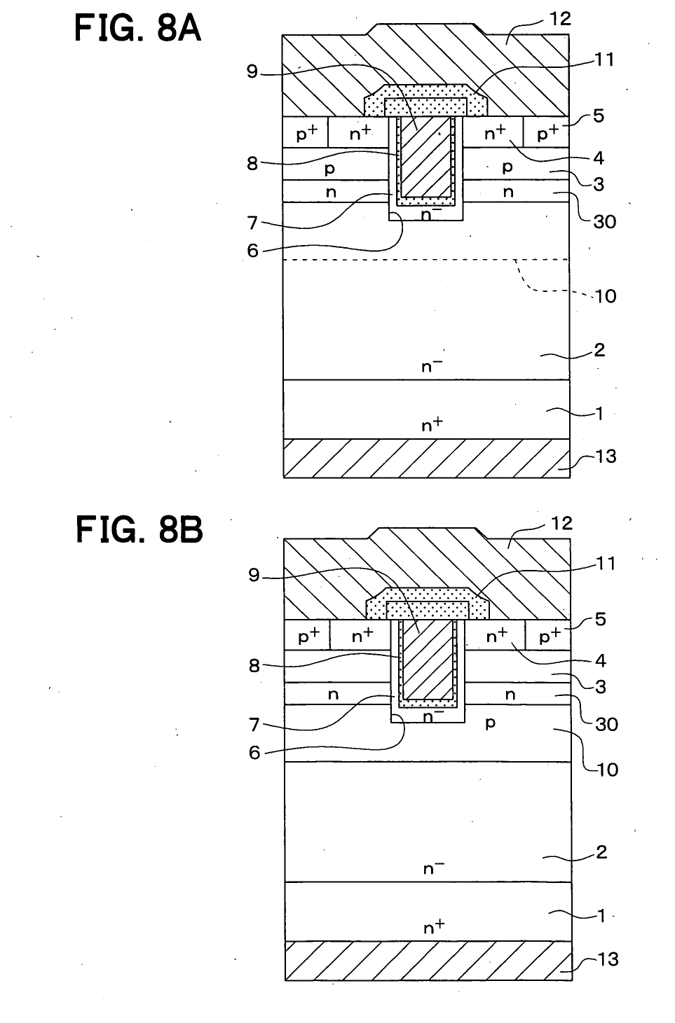

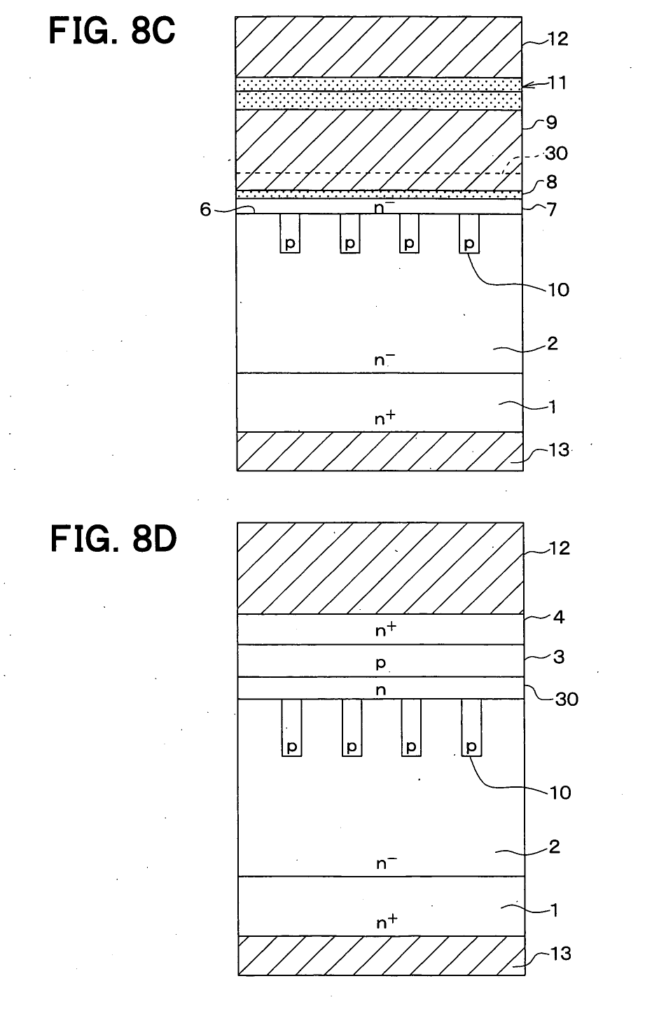

FIG. 7 shows the SiC semiconductor device having a trench gate structure. FIG. 8A shows a cross section of the MOSFET taken along line VIIIA-VIIIA in FIG. 7. Specifically, the cross section of FIG. 8A is taken along a X-Z plane passing through the line VIIIA-VIIIA in FIG. 7. FIG. 8B shows a cross section of the MOSFET taken along line VIIIB-VIIIB in FIG. 7. Specifically, the cross section of FIG. 8B is taken along a X-Z plane passing through the line VIIIB-VIIIB in FIG. 7. FIG. 8C shows a cross section of the MOSFET taken along line VIIIC-VIIIC in FIG. 7. Specifically, the cross section of FIG. 8C is taken along a Y-Z plane passing through the line VIIIC-VIIIC in FIG. 7. FIG. 8D shows a cross section of the MOSFET taken along line VIIID-VIIID in FIG. 7. Specifically, the cross section of FIG. 8D is taken along a Y-Z plane passing through the line VIIID-VIIID in FIG. 7.

As shown in FIG. 7, in the MOSFET, a N type current dispersion layer 30 is formed between the N− type drift layer 2 and the P type base region 3. The current dispersion layer 30 contacts the N type channel layer 7. The current dispersion layer 30 has the N type impurity such as phosphorus with an impurity concentration, which is higher than the drift layer 2. Preferably, the impurity concentration of the current dispersion layer 30 is higher than the channel layer 7. For example, the impurity concentration of the current dispersion layer 30 is in a range between 2.0×10¹⁵/cm³ and 1.0×10¹⁷/cm³. The thickness of the current dispersion layer 30 is arbitrarily set. In the present embodiment, the trench 6 has a predetermined thickness so that the trench 6 penetrates the current dispersion layer 300. For example, the thickness of the trench 6 is about 0.3 μm. The P type deep layer 10 is formed under the current dispersion layer 30. Thus, the deep layer 10 and the base region 3 are divided by the current dispersion layer 30. The deep layer 10 has the depth from the bottom of the current dispersion layer 30, and the depth is in a range between 0.6 μm and 1.0 μm. The impurity concentration, the width and the distance between two adjacent deep layers 10 are substantially the same as those in FIG. 1.

The function of the MOSFET in FIG. 7 is fundamentally similar to the function of the MOSFET in FIG. 1. When the device turns on, the current flowing through the channel layer 7 dispersively flows in a wide range of the drift layer 2 since the current flowing area is expanded by the current dispersion layer 30 in a normal line direction of the sidewall of the trench 6. Accordingly, the on-state resistance of the device in FIG. 7 is reduced, compared with the device in FIG. 1.

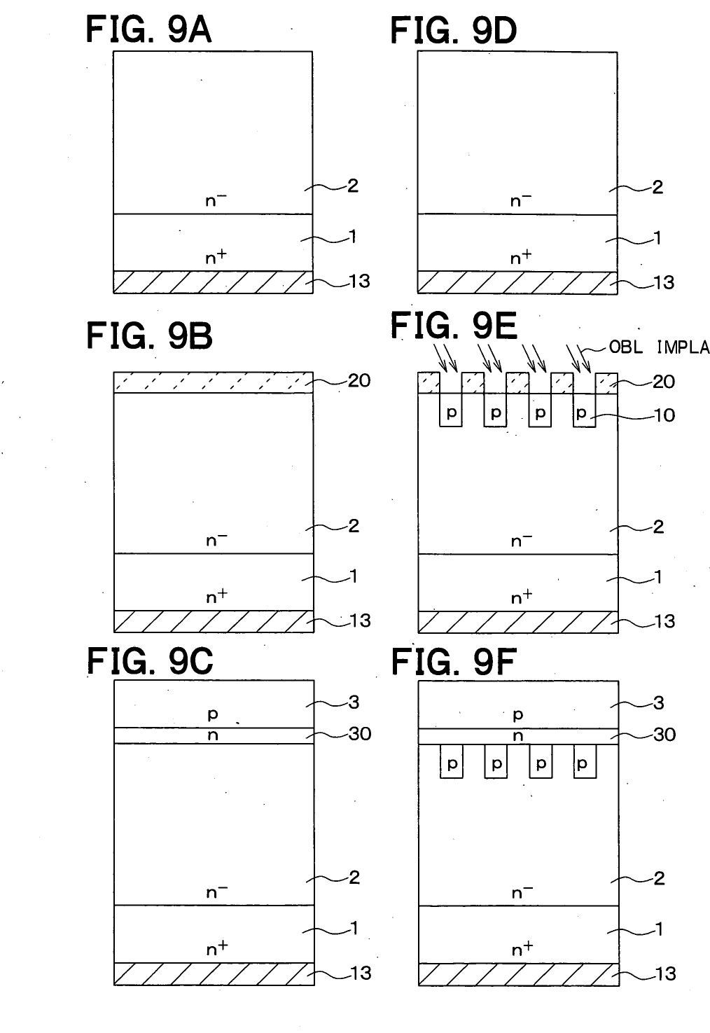

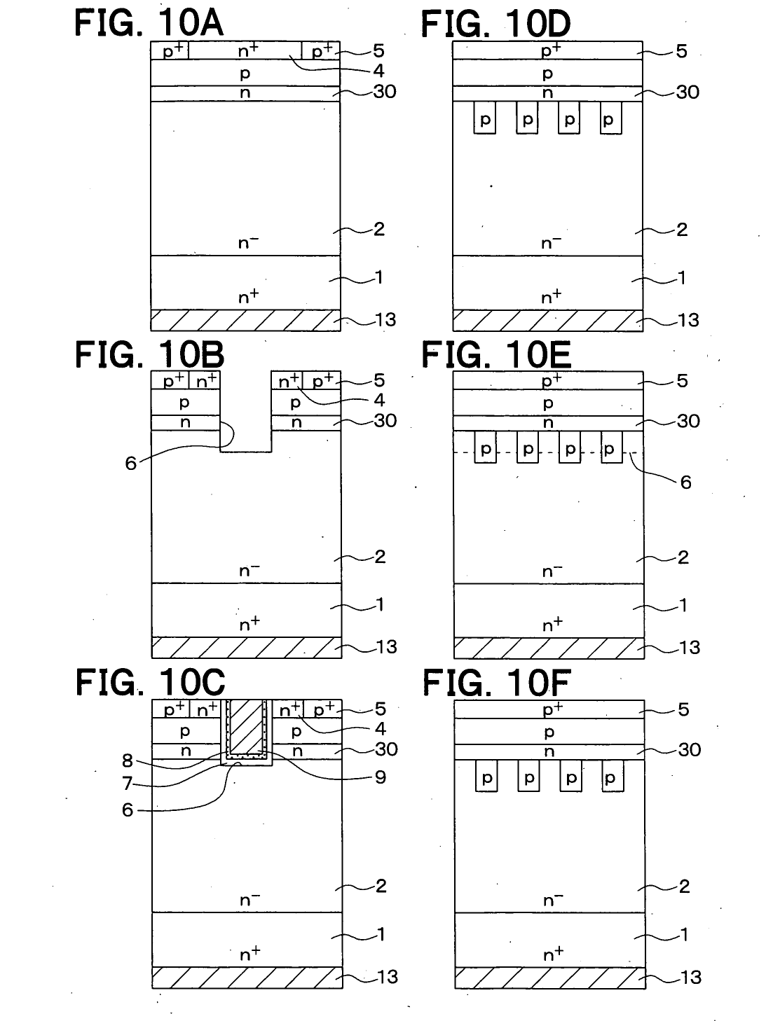

A manufacturing method of the MOSFET in FIG. 7 will be explained as follows with reference to FIGS. 9A to 10F. FIGS. 9A to 9C and 10A to 10C are cross sectional views of the device taken along line VIIIA-VIIIA passing through a plane in parallel to the X-Z plane. FIGS. 9D to 9F and 10D to 10F are cross sectional views of the device taken along line VIIID-VIIID passing through a plane in parallel to the Y-Z plane.

Steps shown in FIGS. 9A, 9B, 9D and 9E are similar to the steps in FIGS. 5A, 5B, 5D and 5E. Thus, the drain electrode 13 is formed on the backside of the substrate 1, and the drift layer 2 is formed on the front side of the substrate 1. Further, the deep layer 10 is formed. In this case, when the deep layer 10 is formed, the oblique ion implantation for implanting the ion with canceling the offset angle of the drift layer 2 and the substrate 1 is performed. Thus, the deep layer 10 is formed at a deep position. Further, in the deep layer 10, the impurity concentration in the deep layer 10 becomes lower as the depth of the deep layer 10 becomes larger. Thus, the deep layer 10 has concentration gradient.

In a step shown in FIGS. 9C and 9F, the current dispersion layer 30 is epitaxially grown on the surface of the drift layer 2 and the deep layer 10. Then, the base region 3 is epitaxially grown on the surface of the current dispersion layer 30. Then, steps shown in FIGS. 10A to 10F are performed similar to the steps shown in FIGS. 6A to 6F. Further, a step for forming the interlayer insulation film 12, a step for forming a contact hole, and a step for forming the gate wiring and the source electrode 11 are performed. Thus, the MOSFET shown in FIG. 7 is completed.

The MOSFET shown in FIG. 7 has the same effects as the MOSFET in FIG. 1.

### Third Embodiment

A SiC semiconductor device according to a third embodiment is similar to the device in FIG. 7. Specifically, the device in the present embodiment, the on-state resistance is reduced.

In the second embodiment, the device includes the current dispersion layer 30. However, the deep layer 10 is separated from the base region 3 with the current dispersion layer 30, so that the deep layer 10 becomes a floating state. Accordingly, the effect of the electric field relaxation is small, compared with a case where the deep layer 10 contacts the base region 3, and the electric potential of the deep layer 10 is fixed to the source potential. In view of this point, in the third embodiment, the on-state resistance of the device is improved.

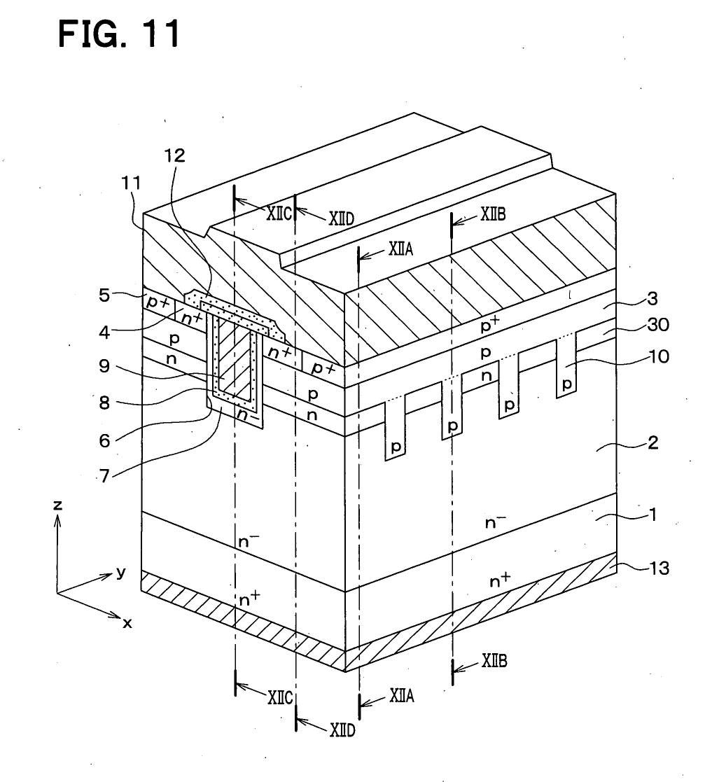

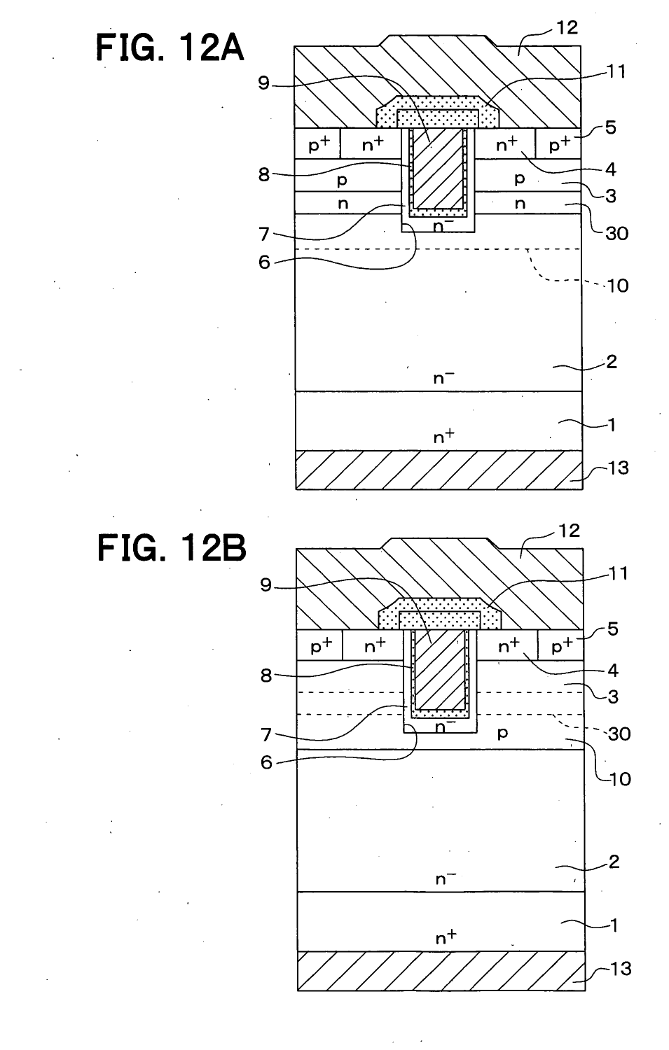

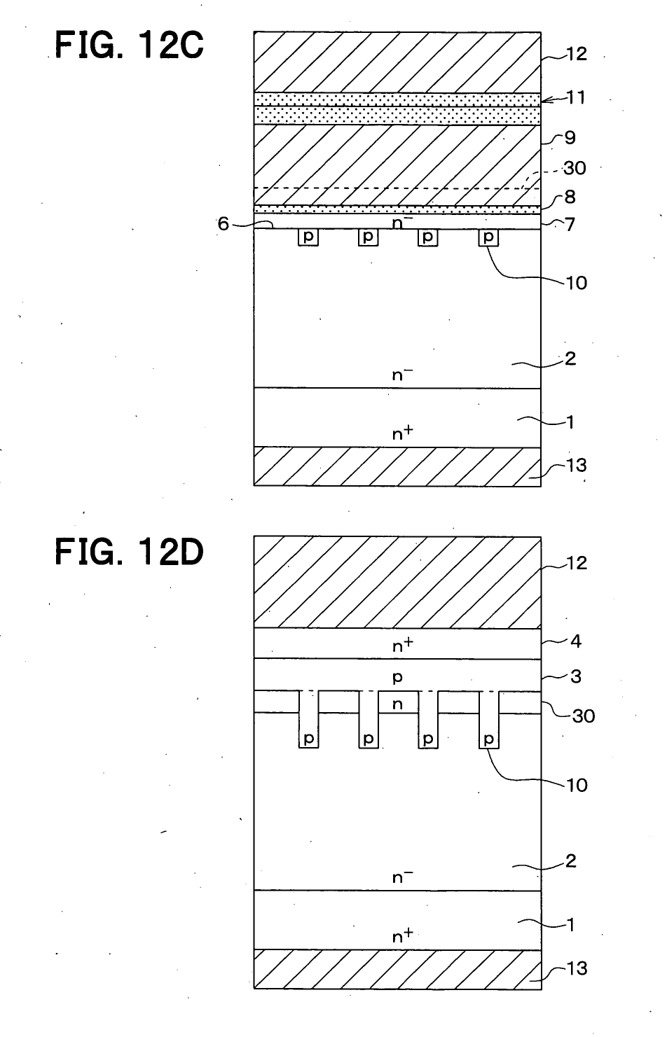

FIG. 11 shows the SiC semiconductor device having a trench gate structure. FIG. 12A shows a cross section of the MOSFET taken along line XIIA-XIIA in FIG. 11. Specifically, the cross section of FIG. 12A is taken along a X-Z plane passing through the line XIIA-XIIA in FIG. 11. FIG. 12B shows a cross section of the MOSFET taken along line XIIB-XIIB in FIG. 11. Specifically, the cross section of FIG. 12B is taken along a X-Z plane passing through the line XIIB-XIIB in FIG. 11. FIG. 12C shows a cross section of the MOSFET taken along line XIIC-XIIC in FIG. 11. Specifically, the cross section of FIG. 12C is taken along a Y-Z plane passing through the line XIIC-XIIC in FIG. 11. FIG. 12D shows a cross section of the MOSFET taken along line XIID-XIID in FIG. 11. Specifically, the cross section of FIG. 12D is taken along a Y-Z plane passing through the line XID-XIID in FIG. 11.

In the MOSFET in FIG. 11, the current dispersion layer 30 is formed between the drift layer 2 and the base region 3, and contacts the channel layer 7. The deep layer 10 is formed from the bottom of the base region 3. The deep layer 10 penetrates the current dispersion layer 30, and the deep layer 10 contacts the base region 3. The deep layer 10 has a depth from the surface of the current dispersion layer 30, and the depth is in a range between 0.6 μm and 1.0 μm. The impurity concentration, the width and the distance between two adjacent deep layers 10 in FIG. 11 are the same as the device in FIG. 1.

The function of the MOSFET in FIG. 11 is similar to the function of the MOSFET in FIG. 1. Further, similar to the device in FIG. 7, when the device turns on, the current flowing through the channel layer 7 dispersively flows in a wide range of the drift layer 2 since the current flowing area is expanded by the current dispersion layer 30 in a normal line direction of the sidewall of the trench 6. Accordingly, the on-state resistance of the device in FIG. 11 is reduced, compared with the device in FIG. 1. Since the deep layer 10 contacts the base region 3, the electric potential of the deep layer 10 is fixed to the source potential. Accordingly, the electric field relaxation effect is improved.

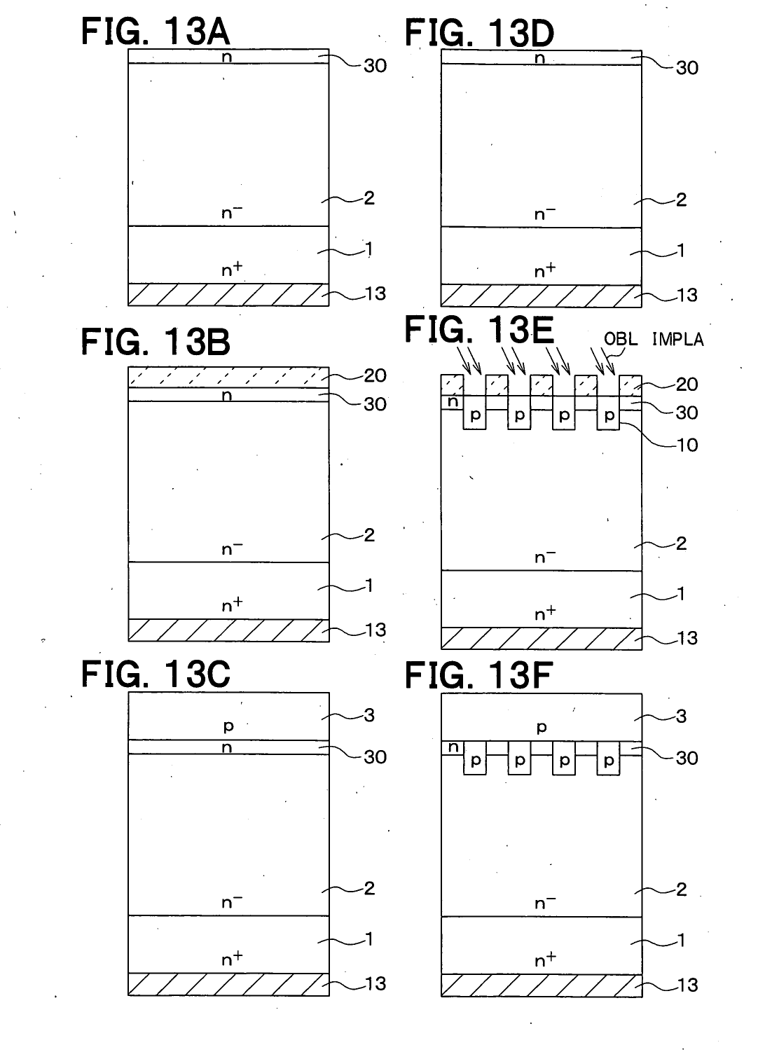

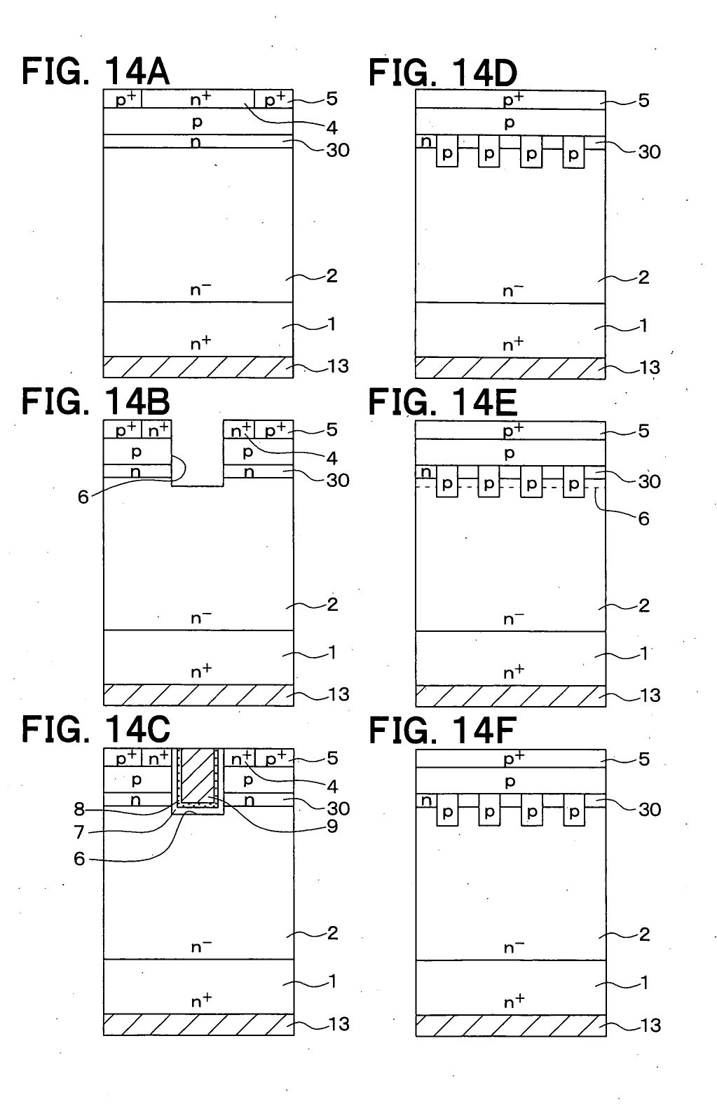

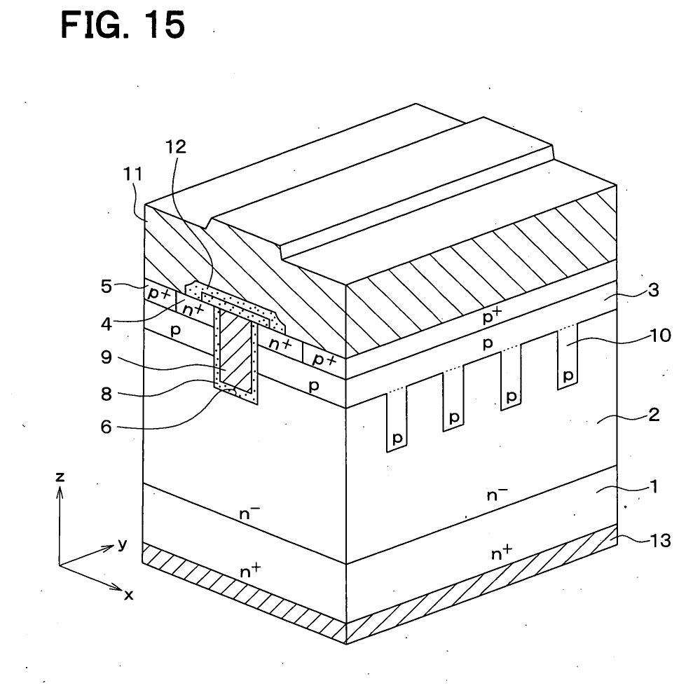

A manufacturing method of the MOSFET having the trench gate structure will be explained. FIGS. 13A to 13C and 14A to 14C are cross sectional views of the device taken along line XIIA-XIIA passing through a plane in parallel to the X-Z plane. FIGS. 13D to 13F and 14D to 14F are cross sectional views of the device taken along line XIID-XIID passing through a plane in parallel to the Y-Z plane.

A step shown in FIGS. 13A and 13D is performed similar to the step in FIGS. 5A and 5D. Thus, the drain electrode 13 is formed on the backside of the substrate 1. The drift layer 2 is formed on the front side of the substrate 1. Then, the N type current dispersion layer 30 is epitaxially grown on the surface of the drift layer 2. The impurity concentration of the current dispersion layer 30 is higher than the drift layer 2. As shown in FIGS. 13B and 13E, the mask 20 is formed on the surface of the current dispersion layer 30, and a similar step as the step in FIGS. 5B and 5E is performed, so that the deep layer 10 is formed. In the step for forming the deep layer 10, the oblique ion implantation with tilting the ion implantation direction to cancel the offset angle of the substrate 1 and the drift layer 2 is performed. Thus, the deep layer is formed at the deep position, and the deep. layer 10 has the concentration gradient so that the impurity concentration in the deep layer 10 becomes lower as the depth in the deep layer 10 becomes deeper.

Then, in the steps shown in FIGS. 13C, 13F and 14A to 14F, process similar to the process in FIGS. 5C, 5F and 6A to 6F is performed. Furthermore, a step for forming the interlayer insulation film 12, a step for forming a contact hole, and a step for forming the source electrode 11 and the gate wiring are performed so that the MOSFET shown in FIG. 11 is completed.

The deep layer 10 in FIG. 11 is formed by the above process similar to the first embodiment. The effects similar to the first embodiment are obtained. Specifically, the ion for forming the deep layer 10 is implanted from the surface of the current dispersion layer 30. Accordingly, the deep layer 10 is formed at a deep position so that the gap between the bottom of the deep layer 10 and the bottom of the trench 6 becomes larger. Thus, the process window for forming the trench 6 is set to be large.

### Fourth Embodiment

A SiC semiconductor device according to a fourth embodiment is an inverse type MOSFET.

FIG. 15 shows the MOSFET having a trench gate structure in the SiC semiconductor device according to the fourth embodiment. The MOSFET in FIG. 15 corresponds to an inverse type MOSFET of the device shown in FIG. 1. Alternatively, the SiC semiconductor device may include inverse type MOSFETS of the devices shown in FIGS. 7 and 11.

In the MOSFET in FIG. 15, the gate oxide film 8 is formed on the surface of the trench 6. However, the MOSFET does not include the N type channel layer 7. Accordingly, the gate oxide film 8 contacts the base region 3 and the source region 4 on the sidewall of the trench 6.

In the MOSFET, when the gate voltage is applied to the gate electrode 9, a part of the base region 3 that contacts the gate oxide film 8 and arranged on the sidewall of the trench 6 provides an inverse type channel so that the current flows between the source electrode 11 and the drain electrode 13.

The above inverse type MOSFET includes the deep layer 10. Thus, when the high drain voltage is applied to the device, the depletion layer expands from the PN junction between the deep layer 10 and the drift layer 2 toward the drift layer side. The high voltage caused by the high drain voltage does not penetrate into the gate oxide film 8. The electric field concentration in the gate oxide film 8 around the bottom of the trench 6 is reduced. The gate oxide film 8 is prevented from being damaged.

A manufacturing method of the device in FIG. 15 is similar to the manufacturing methods for the devices in FIGS. 1, 7 and 11 other than the step for forming the channel layer 7. Thus, the gate oxide film 8 is directly formed on the inner wall of the trench 6. The deep layer 10 in the device in FIG. 15 is also formed by a similar step for the device in FIG. 1. Thus, similar effects according to the first embodiment are obtained.

### Other Embodiments

In the above embodiments, the N type conductivity provides a first type conductivity, and the P type conductivity provides a second type conductivity. Alternatively, the P type conductivity may provide the first type conductivity, and the N type conductivity may provide the second type conductivity so that the SiC semiconductor device includes a P type MOSFET. Although the SiC semiconductor device includes the ttehc gate type MOSFET, the SiC semiconductor device may include a trench gate type IGBT. In this case, the N type substrates 1 shown in FIGS. 1, 7, 11 and 15 are replaced to a P type substrate 1.

Before the trench 6 is formed, the base region 3 and the source region 4 are formed. Alternatively, after the trench 6 is formed, the base region 3 and the source region 4 may be formed by an ion implantation method. In the devices in FIGS. 1, 7 and 11, the source region 4 may contact the gate oxide film 8 when the source region 4 is formed by the ion implantation method. Further, when the base region 3 is formed by the ion implantation method, the base region 3 may be separated from the sidewall of the trench 6, so that the drift layer 2 between the sidewall of the trench 6 and the base region 3 functions as the N type channel layer 7. In this case, the base region 3 and the source region 4 may be formed before or after the trench 6 is formed.

The source region 4 and the body layer 5 are formed by the ion implantation method. Alternatively, one of the source region 4 and the body layer 5 may be formed by an epitaxial growth method.

The base region 3 is electrically connected to the source electrode 11 via the body layer 5. Alternatively, the base region 3 may be electrically connected to the source electrode 11 such that the body layer 5 functions as a merely contact portion. The gate oxide film 8 as the gate insulation film is formed by a thermal oxidation method. Alternatively, the gate oxide film 8 may be formed by other methods. Further, the gate insulation film may include a nitride film. The step for forming the drain electrode 13 may be performed after the step for forming the source electrode 11.

The impurity concentration in the current dispersion layer 30 is higher than the drift layer 2. Alternatively, the impurity concentration of the current dispersion layer 30 may be equal to the drift layer 2. In this case, the trench is formed after the current dispersion layer 30 is formed. The position of the bottom of the trench 6 becomes shallower by the thickness of the current dispersion layer 30 than a case where the device does not include the current dispersion layer 30. Thus, the position of the deep layer 10 becomes deeper from the bottom of the trench 6. Thus, the electric field relaxation effect of the device around the bottom of the trench 6 is higher than the device in FIG. 1.

The longitudinal direction of the deep layer 10 is perpendicular to the longitudinal direction of the trench 6. Alternatively, the deep layer 10 may obliquely intersect with the longitudinal direction of the trench 6. Further, the deep layer 10 and the trench 6 may provide a grip pattern. Furthermore, the deep layer 10 may be in parallel to the longitudinal direction of the trench 6.

In the third embodiment, the deep layer 10 is formed by implanting the ion on the surface of the current dispersion layer 30. In this case, the deep layer 10 is formed at a comparative shallower position than a case where the ion implantation is performed before the current dispersion layer 30 is deposited. However, in a case where the deep layer 10 is formed by the ion implantation method before the current dispersion layer 30 I deposited, the base region 3 is separated from the deep layer 10. Thus, the potential of the deep layer 10 is not fixed to the source potential, so that the electric field relaxation effect is reduced. Accordingly, similar to the second embodiment, before the current dispersion layer 30 is formed, the oblique ion implantation is performed so that a lower portion of the deep layer 10 is formed. Then, after the current dispersion layer 30 is formed, the ion implantation is performed again so that an upper portion of the deep layer 10 is formed. In this case, the deep layer 10 contacts the base region 3 so that the electric field relaxation effect is improved. Further, the deep layer 10 is formed at a deeper position.

In the above embodiments, with using the substrate 1 having the surface orientation slightly tilted from the c-face, the trench 5 is formed to have the sidewall with the normal line of a [11-20]-direction. Alternatively, with using the substrate 1 having the surface orientation slightly tilted from a (0001)-face, the trench 5 may be formed to have the sidewall with the normal line of a [1-100]-direction.

Here, when the crystal orientation is defined, a bar is put on an index. In the present specification, instead of putting the bar on the index, the bar is put in front of the index. For example, a (000-1)-face represents (0001)-face.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A method for manufacturing a SiC semiconductor device comprising:
forming a drift layer made of SiC and having a first conductive type on a first side of a substrate made of SiC and having one of the first conductive type and a second conductive type, wherein the substrate has a face orientation tilted from a predetermined face orientation with a predetermined offset angle, and the drift layer has a face orientation corresponding to the face orientation of the substrate;
forming a mask on a surface of the drift layer, obliquely implanting a second conductive type impurity with using the mask on the drift layer, and activating the second conductive type impurity so that a deep layer having the second conductive type is formed in the drift layer;
forming a base region made of SiC and having the second conductive type on the deep layer and the drift layer;
implanting a first conductive type impurity on a part of the base region so that a source region made of SiC and having the first conductive type is formed, wherein the source region has an impurity concentration higher than the drift layer;
forming a trench on a surface of the source region to penetrate the source region and the base region and to reach the drift layer, wherein the trench has a bottom, which is shallower than a bottom of the deep layer;
forming a channel layer made of SiC and having the first conductive type in the trench;
forming a gate insulation film on a surface of the channel layer in the trench;
forming a gate electrode on the gate insulation film in the trench;
forming a source electrode on the source region and the base region so that the source electrode is electrically coupled with the source region and the base region; and
forming a drain electrode on a second side of the substrate, wherein
in the obliquely implanting the second conductive type impurity, the impurity is implanted in a direction where a difference between the direction of implantation and a normal line of the predetermined face orientation is reduced.

2. The method according to claim 1, further comprising:
forming a current dispersion layer made of SiC and having the first conductive type on the deep layer and the drift layer before the forming the base region, wherein
the current dispersion layer has an impurity concentration higher than the drift layer,
in the forming a base region, the base region is formed on the current dispersion layer.

3. The method according to claim 1, wherein
in the obliquely implanting the second conductive type impurity, the direction of implantation is parallel to the normal line of the predetermined face orientation.

4. The method according to claim 3, wherein
the predetermined offset angle is in a range between two degrees and eight degrees.

5. The method according to claim 1, wherein
the deep layer has an impurity concentration with concentration gradient so that the impurity concentration of the deep layer becomes lower as a depth of the deep layer becomes deeper.

6. A method for manufacturing a SiC semiconductor device comprising:
forming a drift layer made of SiC and having a first conductive type on a first side of a substrate made of SiC and having one of the first conductive type and a second conductive type, wherein the substrate has a face orientation tilted from a predetermined face orientation with a predetermined offset angle, and the drift layer has a face orientation corresponding to the face orientation of the substrate;
forming a current dispersion layer having the first conductive type on the drift layer, wherein the current dispersion layer has an impurity concentration higher than the drift layer, wherein the current dispersion layer has a face orientation corresponding to the face orientation of the substrate;
forming a mask on a surface of the current dispersion layer, obliquely implanting a second conductive type impurity with using the mask on the current dispersion layer, and activating the second conductive type impurity so that a deep layer having the second conductive type is formed in the current dispersion layer and the drift layer;
forming a base region made of SiC and having the second conductive type on the deep layer and the current dispersion layer;
implanting a first conductive type impurity on a part of the base region so that a source region made of SiC and having the first conductive type is formed, wherein the source region has an impurity concentration higher than the drift layer;
forming a trench on a surface of the source region to penetrate the source region and the base region and to reach the current dispersion layer or the drift layer, wherein the trench has a bottom, which is shallower than a bottom of the deep layer;
forming a channel layer having the first conductive type in the trench;
forming a gate insulation film on a surface of the channel layer in the trench;
forming a gate electrode on the gate insulation film in the trench;
forming a source electrode on the source region and the base region so that the source electrode is electrically coupled with the source region and the base region; and
forming a drain electrode on a second side of the substrate, wherein
in the obliquely implanting the second conductive type impurity, the impurity is implanted in a direction where a difference between the direction of implantation and a normal line of the predetermined face orientation is reduced.

7. The method according to claim 6, wherein
in the obliquely implanting the second conductive type impurity, the direction of implantation is parallel to the normal line of the predetermined face orientation.

8. The method according to claim 7, wherein
the predetermined offset angle is in a range between two degrees and eight degrees.

9. The method according to claim 6, wherein
the deep layer has an impurity concentration with concentration gradient so that the impurity concentration of the deep layer becomes lower as a depth of the deep layer becomes deeper.

10. A method for manufacturing a SiC semiconductor device comprising:
forming a drift layer made of SiC and having a first conductive type on a first side of a substrate made of SiC and having one of the first conductive type and a second conductive type, wherein the substrate has a face orientation tilted from a predetermined face orientation with a predetermined offset angle, and the drift layer has a face orientation corresponding to the face orientation of the substrate;
forming a mask on a surface of the drift layer, obliquely implanting a second conductive type impurity with using the mask on the drift layer, and activating the second conductive type impurity so that a deep layer having the second conductive type is formed in the drift layer;
forming a base region made of SiC and having the second conductive type on the deep layer and the drift layer;
implanting a first conductive type impurity on a part of the base region so that a source region made of SiC and having the first conductive type is formed, wherein the source region has an impurity concentration higher than the drift layer;
forming a trench on a surface of the source region to penetrate the source region and the base region and to reach the drift layer, wherein the trench has a bottom, which is shallower than a bottom of the deep layer;
forming a gate insulation film on an inner wall of the trench;
forming a gate electrode on the gate insulation film in the trench;
forming a source electrode on the source region and the base region so that the source electrode is electrically coupled with the source region and the base region; and
forming a drain electrode on a second side of the substrate, wherein
in the obliquely implanting the second conductive type impurity, the impurity is implanted in a direction where a difference between the direction of implantation and a normal line of the predetermined face orientation is reduced.

11. The method according to claim 10, further comprising:
forming a current dispersion layer made of SiC and having the first conductive type on the deep layer and the drift layer before the forming the base region, wherein
the current dispersion layer has an impurity concentration higher than the drift layer,
in the forming a base region, the base region is formed on the current dispersion layer.

12. The method according to claim 10, wherein
in the obliquely implanting the second conductive type impurity, the direction of implantation is parallel to the normal line of the predetermined face orientation.

13. The method according to claim 12, wherein
the predetermined offset angle is in a range between two degrees and eight degrees.

14. The method according to claim 10, wherein
the deep layer has an impurity concentration with concentration gradient so that the impurity concentration of the deep layer becomes lower as a depth of the deep layer becomes deeper.

15. A method for manufacturing a SiC semiconductor device comprising:
forming a drift layer made of SiC and having a first conductive type on a first side of a substrate made of SiC and having one of the first conductive type and a second conductive type, wherein the substrate has a face orientation tilted from a predetermined face orientation with a predetermined offset angle, and the drift layer has a face orientation corresponding to the face orientation of the substrate;
forming a current dispersion layer having the first conductive type on the drift layer, wherein the current dispersion layer has an impurity concentration higher than the drift layer, wherein the current dispersion layer has a face orientation corresponding to the face orientation of the substrate;
forming a mask on a surface of the current dispersion layer, obliquely implanting a second conductive type impurity with using the mask on the current dispersion layer, and activating the second conductive type impurity so that a deep layer having the second conductive type is formed in the current dispersion layer and the drift layer;
forming a base region made of SiC and having the second conductive type on the deep layer and the current dispersion layer;
implanting a first conductive type impurity on a part of the base region so that a source region made of SiC and having the first conductive type is formed, wherein the source region has an impurity concentration higher than the drift layer;
forming a trench on a surface of the source region to penetrate the source region and the base region and to reach the current dispersion layer or the drift layer, wherein the trench has a bottom, which is shallower than a bottom of the deep layer;
forming a gate insulation film on an inner wall of the trench;
forming a gate electrode on the gate insulation film in the trench;
forming a source electrode on the source region and the base region so that the source electrode is electrically coupled with the source region and the base region; and
forming a drain electrode on a second side of the substrate, wherein
in the obliquely implanting the second conductive type impurity, the impurity is implanted in a direction where a difference between the direction of implantation and a normal line of the predetermined face orientation is reduced.

16. The method according to claim 15, wherein
in the obliquely implanting the second conductive type impurity, the direction of implantation is parallel to the normal line of the predetermined face orientation.

17. The method according to claim 16, wherein
the predetermined offset angle is in a range between two degrees and eight degrees.

18. The method according to claim 15, wherein
the deep layer has an impurity concentration with concentration gradient so that the impurity concentration of the deep layer becomes lower as a depth of the deep layer becomes deeper.
